(19) United States
(12) Patent Application Publication
(10) Pub. No.: US 2009/0321876 A1
(43) Pub. Date: Dec. 31, 2009

(54) SYSTEM WITH RADIO FREQUENCY INTEGRATED CIRCUITS

(76) Inventor: Telesphor Kamgaing, Chandler, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/165,487

(22) Filed: Jun. 30, 2008

(51) Int. Cl. H01L 29/00; H01L 21/60

(52) U.S. Cl. 257/531; 438/121; 257/E21.506; 257/E29.001

(57) ABSTRACT

A semiconductor package comprises an integrated radio frequency circuit that may be provided in a semiconductor die. A ground plane may be attached to the semiconductor die. The ground plane is selectively patterned in a direction that is perpendicular to an inductor trace of an inductor of the radio frequency circuit. In some embodiments, the ground plane may be selectively patterned to allow an eddy current in the semiconductor package not to flow in opposite direction of a main current in the inductor. In one example, the ground plane may be a portion of the semiconductor package substrate or a die back metallization of the semiconductor die.

### BACKGROUND

Some semiconductor packages may contain radio frequency integrated circuits (RFIC). Some packages may provide radio and/or digital functionalities. Some RFICs may utilize integrated inductors. Some factors may impact inductor quality factor and/or inductance of the integrated inductors, e.g., including a thickness of an RFIC die, an epi layer below an inductor, a package-level or die-level ground plane, an inductor/ground interaction in an RFIC.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIGS. 1A to 1C are schematic figures of a system according to an embodiment of the invention.

FIGS. 2A and 2B are schematic figures of an embodiment of a ground plane.

FIG. 3 is a schematic flow chart of a method according to an embodiment of the invention.

FIG. 4 is a schematic figure of a system according an embodiment of the invention.

FIG. 5A and 5B are schematic figures of a system according to some embodiments of the present invention.

FIG. 6 is a schematic flow chart of a method according to an embodiment of the invention.

FIG. 7 is a schematic flow chart of a method according to an embodiment of the invention.

FIG. 8 is a schematic flow chart of a method according to an embodiment of the invention.

### DETAILED DESCRIPTION

In the following detailed description, references are made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following description may include terms, such as upper, lower, top, bottom, first, second, etc. that are used for descriptive purposes only and are not to be construed as limiting.

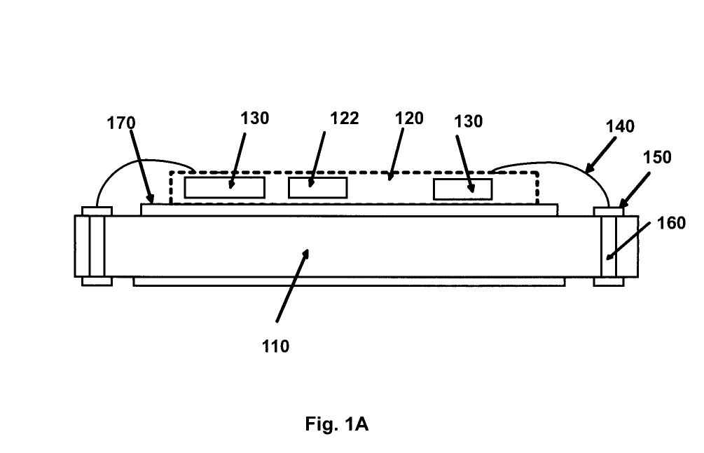

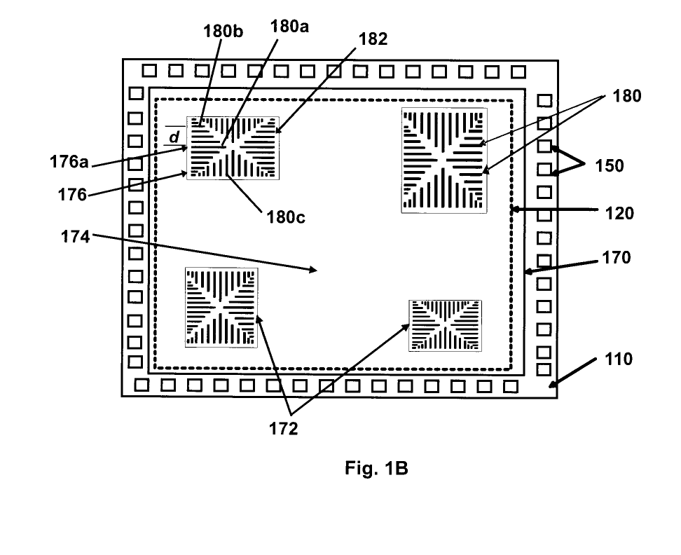

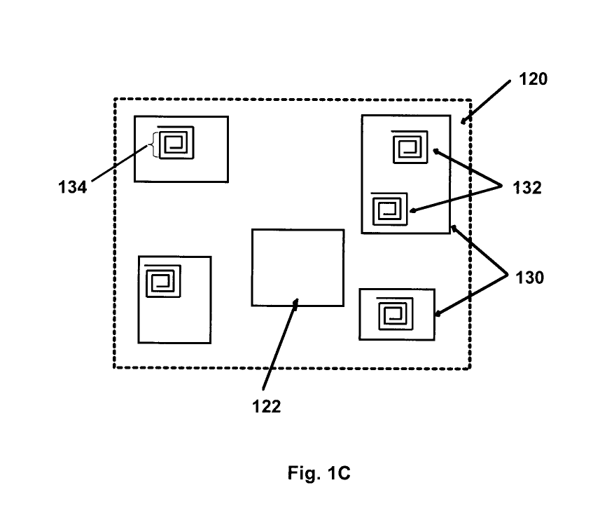

FIG. 1A is a cross-sectional view of an embodiment of a system 100 and FIG. 1B illustrate an embodiment of a ground plane on the system 100. The system 100 may comprise a semiconductor package substrate 110. In one embodiment, the semiconductor package substrate 110 may be coupled to a semiconductor die 120 that may be located on the semiconductor package substrate 110. The semiconductor die 120 may be electrically coupled to the semiconductor package substrate 110, e.g., by one or more bonding wires 140; however, in some embodiments, any other interconnects may be used to couple the chip 120 to the substrate 110. A bonding pad 150 may be disposed on the semiconductor package substrate 110 to couple a bonding wire 140 to one or more internal interconnects or external interconnects on the semiconductor package substrate 110, such as plated through holes (PTH) 160, or vias.

One example of the semiconductor package substrate 110 may comprise a printed circuit board (PCB) or a printed wiring board (PWB); however, any other suitable substrate may be utilized, including flex substrates such as folded flex substrates or flexible polyimide tape, laminate substrates, buildup substrates, ceramic substrates, flame retardant (FR-4) substrate, or tape automated bonding (TAB) tape material.

In one embodiment, examples of the semiconductor die 120 may comprise multiple-input multiple-output (MIMO) transceivers, system on chip (SOC) chips or any other integrated circuits that may comprise integrated electrical circuit components. For example, the semiconductor die 120 may comprise one or more radio frequency (RF) circuits or components 130. Examples of the radio frequency circuits 130 may comprise low-noise amplifiers (LNA), power amplifiers (PA), radio frequency front-end modules (FEM), RF switches, radio frequency integrated circuits (RFIC) or any other radio frequency circuits. For example, a radio frequency circuit 130 may comprise one or more, e.g., on-chip spiral inductors 132. In another embodiment, the semiconductor die 120 may further comprise one or more digital circuits or components 122; however, in some embodiment, the semiconductor die 120 may not comprise digital circuits. Examples of the digital circuits 122 may comprise baseband components or media access controller (MAC), flash memory, DRAM or some kind of processors. In one embodiment, the radio frequency circuits 130 may each be provided on different locations of the semiconductor die 120, e.g., to provide a reduced interference and/or an improved noise isolation.

Referring to FIG. 1B, the system 100 may further comprise a ground plane 170 that may be disposed between the semiconductor die 120 to the semiconductor package substrate 110; however, in some embodiments, the semiconductor package substrate 110 may not be required. In one embodiment, the ground plane 170 may be used to attach the semiconductor die 120 to the semiconductor package substrate 110. Examples of the ground plane 170 may comprise die attach metal. In another embodiment, the ground plane may use a metal or alloys of different metals, e.g., include aluminum (Al), copper (Cu), aluminum copper (AlCu), gold (Au), AlSiCu, TiWAu. Techniques for adding the ground plane 170 may include sputtering, chemical vapor deposition or plating.

With reference to FIG. 1B, the ground plane 170 may be selectively patterned to provide one or more ground traces 180, e.g., at a top surface of the ground plane 170. For example, the ground plane 170 may be selectively patterned to provide the ground traces 180 at a portion 172 that may be underneath a radio frequency circuit 132. In another embodiment, the patterned portion 172 may be selectively patterned in a direction that may be perpendicular to an inductor trace 134 of a spiral inductor 132.

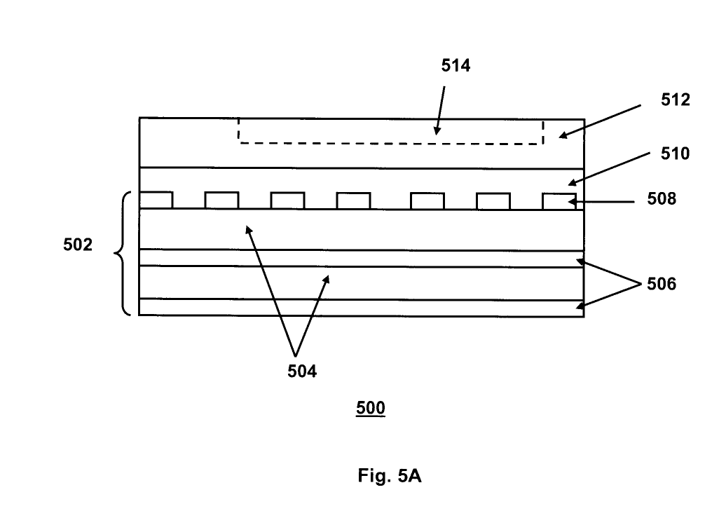

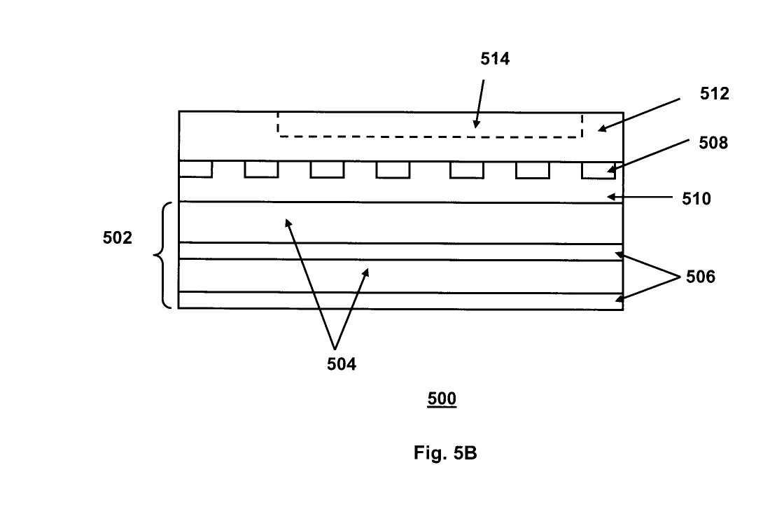

Although FIG. 1A illustrates a ground plane 170, some embodiments may utilize a ground plane that may be a patterned metal layer of a semiconductor package (e.g., FIG. 5A) or a die back metallization attached to a back of a semiconductor die (e.g., FIG. 5B). In one embodiment, a ground trace width may be smaller than an inductor trace width; however, in some embodiments, a ground trace width may not be smaller. In another embodiment, a ground trace spacing may be equal to or larger than an inductor trace spacing; however, in some embodiments, a ground trace spacing may be smaller than an inductor trace spacing.

Referring to FIG. 5A, it is illustrated an embodiment of a system 500. The system 500 may comprise a multi-layered semiconductor package substrate 502; however, in some embodiments, the semiconductor package substrate 502 may comprise a multi-layered structure. The semiconductor substrate 502 may comprise one or more metal layers 506 and one or more buildup layers 504 that may be interleaved with each other. In one embodiment, the semiconductor substrate 502 may further comprise a metal layer 508a, e.g., on top of the semiconductor substrate 502. For example, the metal layer 508a may have a pattern, e.g., as shown in FIG. 1B, 2A or 2B. In one embodiment, a pattern may be formed during package fabrication; however, in some embodiments, the pattern may be formed first and may be co-fired with the semiconductor package substrate. A die attach material 510 may be used to attach a semiconductor die 512 that may comprise a radio frequency circuit 514 to the semiconductor package substrate 502.

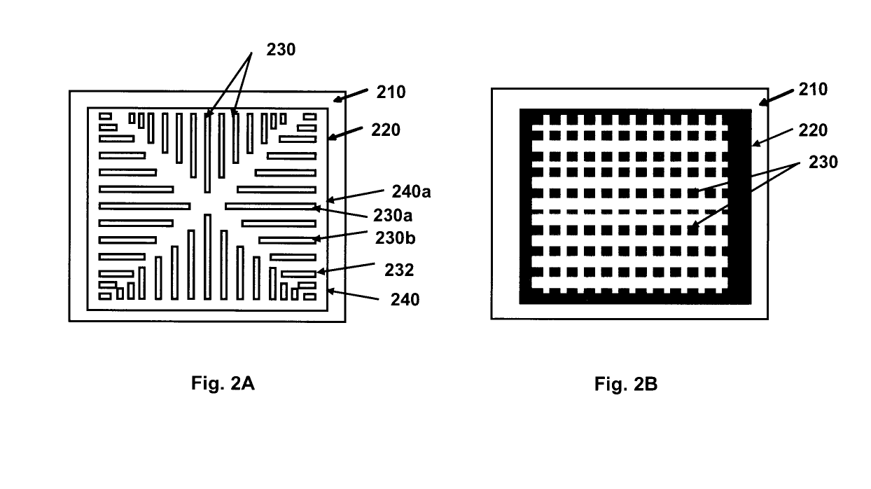

Referring to FIG. 5B, the semiconductor die 512 may comprise a die back metallization 508b. For example, the die back metallization 508b may have a pattern as shown in FIG. 1B, FIG. 2A or FIG. 2B. Techniques for adding the die back metallization 508b to the semiconductor die 512 may include sputtering, chemical vapor deposition or plating.

In one embodiment, a location of the patterned portion 172 may correspond to a location of a corresponding radio frequency circuit 130. For example, a patterned portion 172 may be provided underneath a corresponding radio frequency circuit 130. In another embodiment, the patterned portion 172 may be located underneath a spiral inductor 132. In yet another embodiment, an area of the patterned portion 172 may be correspond to or equal to an area of a corresponding radio frequency circuit 130. In another embodiment, an area of the patterned portion 172 may correspond to or be equal to an area of a corresponding spiral inductor 132. Referring to FIG. 1B, the ground plane 170 may comprise an un-patterned portion 174 that may correspond to a digital circuit 122. In another embodiment, an un-patterned portion 174 may be under a portion of the semiconductor die 120 where a radio frequent circuit 130 is absent.

Referring to FIGS. 1B and 1C, in one embodiment, a ground trace 180 may be perpendicular to a corresponding inductor trace 134. Referring to FIG. 1B, in one embodiment, a patterned portion 172 may comprise a set of one or more ground traces 180 that may be parallel to each other. A patterned portion 172 may be patterned to have a ground trace 180 that may have an end 182 to be aligned along, e.g., a corresponding side 176 of the patterned portion 172. In another embodiment, a length of a ground trace 180 may have a relationship with a distance d from the ground trace 180 to a center 176a of a corresponding side 176. For example, a first ground trace 180a may have a larger length than that of a second ground trace 180b that locates farther from the center 176a. Referring to FIG. 1B, in another embodiment, a ground trace 180 with an end to be aligned along one side of a patterned portion 172 may not intersect another ground trace 180 with an end to be aligned along another side of the patterned portion 172.

In one embodiment, the ground plane 170 may be selectively patterned to force an induced current, e.g., an eddy current, in the system 100 that may not flow in opposite direction to a second current, e.g., main current, in a spiral inductor 132. For example, the ground plane 170 may have a pattern to force the induced current to flow in a direction different from an opposite direction to the main current. In another embodiment, the ground plane 170 may be selectively patterned to allow the eddy current to flow in a direction that may be perpendicular to a main current in a spiral inductor 132.

FIGS. 2A and 2B illustrate embodiments of a ground plane 220. For example, the ground plane 220 may be disposed to attach a semiconductor die (not shown) to a semiconductor package substrate 210; however, in some embodiments, the semiconductor package substrate 210 may not be required. Examples of the semiconductor die may comprise a RFIC die, e.g., including low noise amplifiers, RF switches, integrated passive devices (IPD) or power amplifiers, that may not comprise digital circuits, digital components or digital functionalities. In one embodiment, a ground plane 220 may be selectively patterned in a direction that may be perpendicular to an inductor trace in the semiconductor die to provide one or more traces 230. For example, an area of the whole ground plane 220 may be selectively patterned.

Referring to FIG. 2A, in one embodiment, the ground plane 220 may have a pattern that may be similar to a pattern of a patterned portion 172 of FIG. 1B. For example, an end 232 of a ground trace 230 may align along a side 240 of the ground plane 220. A length of a ground trace 230 may have a relationship with a center portion 240a of a corresponding side 240. For example, a first ground trace 230a that locates in proximity to or at the center portion 240a may have a length that is larger than a length of a second ground trace 230b that may locate farther from the center portion 240a. In yet another embodiment, a set of one or more ground traces 230 that align along a side of the ground plane 220 may not intersect a set of one or more ground traces 230 that align along another side of the ground plane 220. In another embodiment, referring to FIG. 2B, the ground plane 220 may be selectively patterned in a direction that may be perpendicular to an inductor trace of the semiconductor die to provide one or more ground traces 230 that may arrange in a grid; however, in some embodiments, the ground traces 230 may arrange in a matrix or an array. In another embodiment, referring to FIG. 2B, one or more ground traces 230 may be provided to align in a direction that is perpendicular to an inductor trace (not shown). For example, one or more ground traces 230 may be provided to align in the direction of patterning. In yet another embodiment, the ground plane 220 of FIG. 2A or FIG. 2B may provide an eddy current that may not flow in an opposite direction to a main current in an inductor trace of the semiconductor die.

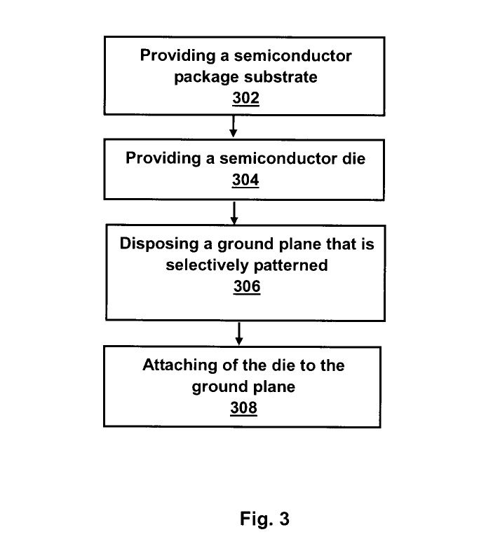

FIG. 3 illustrates an embodiment of a method. In one embodiment, the method may be described with reference to FIGS. 1A-1C. Referring to FIG. 3, in block 302, a semiconductor substrate 110 may be provided. In block 304, the semiconductor die 120 may be provided. In one embodiment, the semiconductor die 120 may be thinned to a thickness. For example, a thickness of the semiconductor die 120 may be around 200 um or less. In another embodiment, a thickness of the semiconductor die 120 may be around 100 um or less. In some embodiments, the semiconductor package substrate 110 may not be required in some semiconductor packages, e.g., quadflat no lead (QFN) or thin array plastic package (TAPP).

In block 306, a ground plane 170 may be provided. The ground plane 170 may be selectively patterned to provide one or more ground traces 180 that may be perpendicular to an inductor trace 134 in a radio frequency circuit 130. The ground plane 170 may be selectively patterned in a direction that may be perpendicular to an inductor trace 134 in a radio frequency circuit 130. In one embodiment, the ground plane 170 may be partially patterned at a location that may correspond to a radio frequency circuit 130. For example, the ground plane 170 may be partially patterned at a location that may be under a radio frequency circuit 130. In another embodiment, a portion of the ground plane 170 that corresponds to a digital circuit 122 may not be patterned.

In block 308, the ground plane 170 may be used to attach the semiconductor die 120 to the semiconductor package substrate 110; however, in some embodiments, the semiconductor package substrate 110 may not be required.

In yet another embodiment, the semiconductor die 120 may comprise a RFIC die that may not provide digital functionalities and a whole surface of the ground plane 170 may be selectively patterned to provide one or more ground traces 180. In yet another embodiment, the whole ground plane 170 may be selectively patterned to provide a pattern of FIG. 2A or 2B. In one embodiment, the ground plane 170 may be selectively patterned to induce an eddy current on the system 100 that may not flow in opposite direction to a main current in the spiral inductor 132. In another embodiment, the ground plane 170 may be patterned to provide a patterned portion 172 that may allow an eddy current to be induced on the system 100 to flow in a direction that may be perpendicular to a main current in the spiral inductor 132. While the method of FIG. 3 is illustrated to comprise a sequence of processes, the method in some embodiments may perform illustrated processes in a different order.

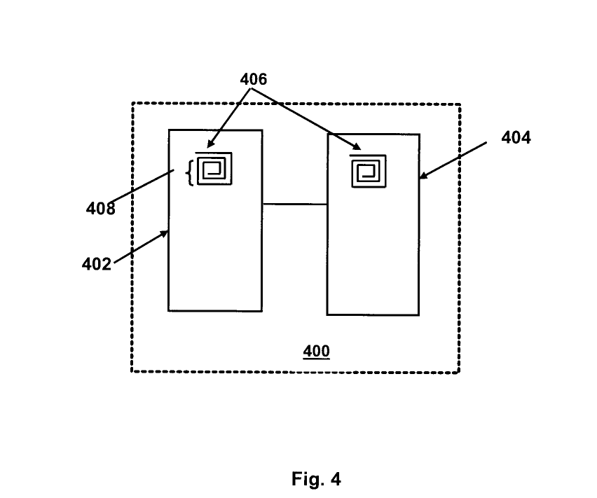

FIG. 4 illustrates an embodiment of a system 400 that may be formed in a package. In one embodiment, the system 400 may comprise a RF module 402 that may be electrically coupled to a transceiver 404; however, in some embodiments, the system 400 may not comprise the transceiver 404. In one embodiment, examples of the RF module 402 may comprise low noise amplifier, voltage controlled oscillator (VCO), mixer, power amplifier, or any other RF front end components. In one embodiment, the RF module 402 may be integrated in the same package as the transceiver 404; however, in some embodiments, the RF module 402 and the transceiver 404 may be provided in different packages. In another embodiment, the RF module 402 and/or the transceiver 404 may be provided on a semiconductor package substrate (not shown); however, in some embodiment, the semiconductor package substrate may not be required. A ground plane, e.g., 170 of FIG. 1B or 220 of FIG. 2A or 2B, may be attached to a backside of the RF module 402 and/or the transceiver 404. The ground plane may be selectively patterned in a direction that may be perpendicular to an inductor trace 408 of an inductor 406 in the RF module 402 and/or the transceiver 404. Although FIG. 4 illustrates RF module 402 and transceiver 404, in some embodiments, the system 400 may comprise any other radio and/or digital components, including, e.g., baseband components, MAC components or RFIC chip.

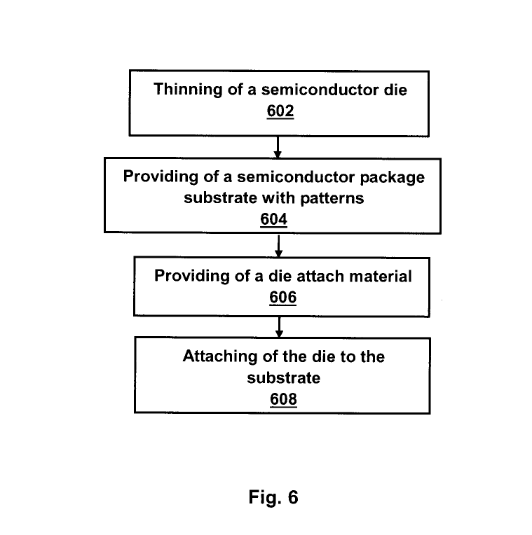

FIG. 6 illustrates an embodiment of a method. In one embodiment, the method may be described with reference to FIG. 5A. Referring to FIG. 6, in block 602, a semiconductor die 512 may be provided. In one embodiment, the semiconductor die 512 may be thinned to a predetermined thickness. In block 604, a semiconductor package substrate 502 may be provided. In one embodiment, one or more metal layers 506 and one or more buildup layers 504 may be formed. In another embodiment, a top metal layer 508a may be formed on a top buildup layer 504. The top metal layer 508a may be selectively patterned to have, e.g., a pattern of FIG. 1B, 2A or 2B. In block 606, a die attach material 510 may be provided. In block 608, the die 512 may be attached to the semiconductor package substrate 502 by the die attach material 510. In one embodiment, the top metal layer 508a may have a thickness of around 30um or less.

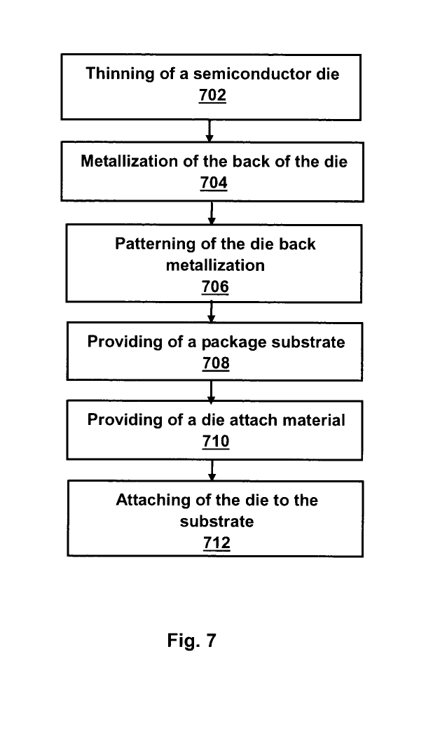

FIG. 7 illustrates an embodiment of a method. In one embodiment, the method may be described with reference to FIG. 5B. Referring to FIG. 7, in block 702, a semiconductor die 512 may be provided. In one embodiment, the semiconductor die 512 may be thinned to a predetermined thickness. In block 704, a die back metallization 508b may be provided on a back side of the semiconductor die 512. In one embodiment, the die back metallization 508b may be selectively patterned to have, e.g., a pattern of FIG. 1B, 2A or 2B. Techniques to create a pattern on the die back metallization 508b may include various types of etching or laser patterning. In block 708, a semiconductor package substrate 502 of FIG. 5B may be provided. In block 710, a die attach material 510 may be provided. In block 712, the die 512 may be attached to the semiconductor package substrate 502 by the die attach material 510 with the back side of the semiconductor die 512 to face the semiconductor package substrate 502. In one embodiment, the die back metallization 508b may have a thickness of around 30 um or less.

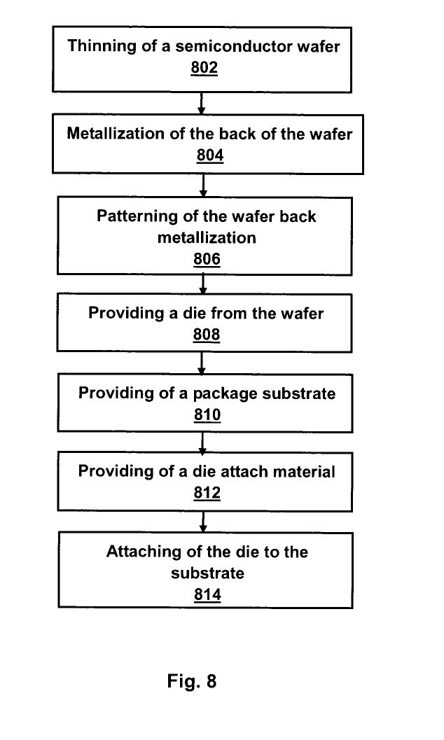

FIG. 8 illustrates an embodiment of a method that may be similar to a method of FIG. 7. In block 802, one embodiment may comprise to thin a semiconductor wafer. In block 804, a wafer back metallization may be provided on a back side of the semiconductor wafer. In block 806, the wafer back metallization may be selectively patterned to, e.g., have a pattern as shown in FIG. 1B, FIG. 2A or FIG. 2B. In block 808, a semiconductor die may be provided from the wafer that may comprise the patterned wafer back metallization. The description of blocks 810 to 814 may make reference to the blocks 708 to 712, respectively.

While the methods of FIGS. 6-8 may be illustrated to comprise a sequence of processes, the method in some embodiments may perform illustrated processes in a different order.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

What is claimed is:

1. A semiconductor package, comprising:
an integrated radio frequency circuit that comprises an inductor;
a ground plane attached to the integrated radio frequency circuit, the ground plane being selectively patterned in a direction that is perpendicular to an inductor trace of the inductor.

2. The package of claim 1, wherein the ground plane comprises a patterned portion that corresponds to the integrated radio frequency circuit.

3. The package of claim 1, wherein the ground plane comprises a ground trace that is under the integrated radio frequency circuit.

4. The package of claim 1, wherein the ground plane is a

5. The package of claim 1, wherein the ground plane is to force an induced eddy current flow in a direction that is different from an opposite direction to a current in the inductor.

6. The package of claim 1, wherein the ground plane is to force an induced eddy current to flow in a direction perpendicular to a current in the inductor.

7. The package of claim 1, wherein the ground plane comprise die attach metal to attach the integrated radio frequency circuit to a semiconductor package substrate.

8. The package of claim 1, wherein the ground plane is a top metal layer of the semiconductor package substrate.

9. The package of claim 1, wherein the ground plane comprise a back metallization disposed on a back side of the integrated radio frequency circuit

10. A method to fabricate a semiconductor package, comprising:
providing a semiconductor die to comprise an inductor; and
providing a ground plane attached to the semiconductor die, wherein the ground plane is selectively patterned in a direction that is perpendicular to an inductor trace of the inductor.

11. The method of claim 10, wherein the ground plane comprises one or more ground traces to induce an eddy current that flows in a direction different from an opposite direction to a current in the inductor.

12. The method of claim 10, wherein the ground plane being selectively patterned comprises to provide a patterned portion that correspond to a location of the inductor.

13. The method of claim 8, wherein the ground plane is a metal layer of a semiconductor package substrate that is attached to the semiconductor die.

14. The method of claim 10, wherein the ground plane is a die back metallization.

15. The method of claim 10, wherein providing a ground plane comprises providing a die back metallization on a back side of the semiconductor die.

16. A system, comprising:
a package;
a radio component disposed in the package, the radio component comprise an inductor trace; and
a ground plane provided under the radio component, the ground plane comprising a ground trace that is patterned in a direction perpendicular to the inductor trace.

17. The system of claim 16, wherein the radio component comprises one of a group that comprises a radio frequency module, a low noise amplifier, a power amplifier, a radio frequency front end module, a mixer.

18. The system of claim 16, wherein the ground plane is a top metal layer of a semiconductor package substrate that is attached to the radio component.

19. The system of claim 16, wherein the ground plane is to allow a first current in the ground plane not to flow in an opposite direction to a second current in the inductor trace.

20. The system of claim 16, wherein the ground place is a metallization provided at a back side of the radio component.

21. The system of claim 16, comprising:
a digital component that is coupled to the radio component, the ground trace being positioned where the digital component is absent.
